(19) United States
(12) Patent Application Publication
(10) Pub. No.: US 2007/0132502 A1
(43) Pub. Date: Jun. 14, 2007

(54) Method and circuit arrangement for limiting the power dissipation of a power semiconductor switch

(76) Inventors: Wolfgang Kollner, Wien (AT); Ludwik Waskiewicz, Vosendorf (AT)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/463,734

(22) Filed: Aug. 10, 2006

(30) Foreign Application Priority Data
Aug. 11, 2005 (DE) 10 2005 038 124.3

(51) Int. Cl. H03K 17/687

(52) U.S. Cl. 327/427

(57) ABSTRACT

Method for limiting the power dissipation of a power semiconductor switch (1) with a control input (20) which is connected to a controller (2), wherein
a measuring device (3) generates an analog power signal (8), the signal amplitude of which corresponds to the current power dissipation in the power semiconductor switch,
a comparator circuit (23) in which a comparison of the signal amplitude of the current power dissipation with a signal amplitude of a reference signal (9) is carried out and which generates a shut-off signal (10) if the signal amplitude of the analog power signal is greater than the signal amplitude of the reference signal, and
the shut-off signal (10) is supplied to the control input (20) of the power semiconductor switch (1).

### PRIORITY

This application claims priority from German Patent Application No. DE 10 2005 038 124.3, which was filed on Aug. 11, 2005, and is incorporated herein by reference in its entirety.

### TECHNICAL FIELD

The invention relates to a method and to a circuit arrangement for limiting the power dissipation in a power semiconductor switch which comprises a control input and is controlled by a controller.

### BACKGROUND

To protect a power semiconductor switch against overload and short-circuiting, short-circuit current limiters are known. There are circuits which when switched on measure the voltage drop occurring at the two load terminals of the power semiconductor switch and compare these with a reference voltage. Depending on the load circuit this voltage drop can reach the potential of the supply voltage when switched on, so a time-lag element has to be fitted to prevent a faulty response. The problem in this case is finding an optimum delay time for the time-lag element as effective protection is also dependent on the wiring in the load circuit. An incorrectly dimensioned time-lag element can cause inadmissibly high heat losses in the power semiconductor switch and damage or even destroy it. This risk exists in particular with a power semiconductor switch which is used in a motor vehicle and is connected to a powerful battery.

What are known as intelligent power semiconductor switches, also called “smart switches”, are also known which, in addition to the actual power switch, include intelligent protective functions which are monolithically integrated in the power semiconductor switch. A protective function of this type can for example be implemented such that an excess temperature is detected and this faulty state is indicated at an output of the intelligent power semiconductor switch. A disadvantage of this is that due to the thermal inertia in the substrate, the excess temperature is indicated too late, or the controller which monitors this output reacts too slowly to this indication.

### SUMMARY

The object of the invention is to ensure that the power dissipation occurring during operation of a power semiconductor switch at no time exceeds a maximum admissible power dissipation during continuous operation specified by the component manufacturer.

A method for limiting the power dissipation of a power semiconductor switch having a control input, may comprise the following steps:
generating, by means of an analog measuring circuit, an analog power dissipation signal which is an image of the current power dissipation occurring during operation of the power semiconductor switch and has a signal level,
comparing the signal level of the current power dissipation with a signal level of a reference signal in an analog comparator circuit,
generating a shut-off signal if the signal level of the power dissipation signal is greater than the signal level of the reference signal,
shutting off the power semiconductor switch via the shut-off signal.

The measuring circuit may comprise an analog multiplier circuit which generates the power dissipation signal by multiplying a first signal which corresponds to the differential voltage at the power circuit terminals of the power semiconductor switch by a second signal which corresponds to the load current carried by the power circuit terminals. The second signal may be formed by a voltage drop which is caused by the load current at a measuring shunt. The comparator circuit can be formed by an analog comparator circuit which has an inverting input and a non-inverting input, and the analog power dissipation signal may be supplied to the inverting input and the reference signal to the non-inverting input. A maximum admissible pulse power dissipation of the power semiconductor switch at a predetermined temperature can be chosen as the reference signal.

A circuit arrangement for limiting the power dissipation of a power semiconductor switch which has a control input, may comprise a measuring circuit which generates an analog power dissipation signal, the signal level of which corresponds to the power dissipation instantaneously occurring in the power semiconductor switch during operation, and a comparator circuit which has an output that is connected to the control input, which carries out a comparison of the signal level of the current power dissipation with a signal level of a reference signal, and which generates a shut-off signal if the signal level of the power dissipation signal is greater than the signal level of the reference signal.

The measuring circuit may comprise an analog multiplier circuit which generates the power dissipation signal by multiplying a first signal which corresponds to the differential voltage at the power circuit terminals of the power semiconductor switch by a second signal which corresponds to the current carried via the power circuit terminals of the power semiconductor switch. The load current of the power semiconductor switch can be carried via a measuring shunt and the second signal corresponds to the voltage drop occurring at this measuring shunt during operation of the power semiconductor switch. The reference signal can be a maximum admissible pulse power dissipation of the power semiconductor switch at a predetermined temperature.

According to the invention an analog measuring circuit is provided by means of which an analog power dissipation signal is generated which is an image of the current power dissipation occurring during operation of the power semiconductor switch. This power dissipation signal is compared in a comparator circuit with a reference signal. The reference signal preferably corresponds to a maximum admissible power dissipation during pulse control operation and at a specific temperature, and this is conventionally specified by technical data provided by the manufacturer of the power semiconductor switch. In the event that the signal level of the power dissipation signal is greater than the signal level of the reference signal, a shut-off signal is generated by the comparator circuit, which signal is supplied to the control terminal of the power semiconductor and causes this to shut off. Both the measuring device and the comparator circuit are implemented on the basis of analog circuit technology. This results in the advantage that a very fast response to an overload state is possible and a higher maximum admissible power dissipation may be permitted in the case of pulse control operation than in the case of continuous operation.

In a preferred embodiment of the invention the measuring circuit comprises an analog multiplier circuit which forms the power dissipation signal by multiplying two signals which each correspond to the potential difference at the power circuit terminals and the load current carried via the power circuit terminals respectively. It is advantageous here that inexpensive analog multiplier components of conventional design may be used.

In terms of circuit engineering, the load current may be detected very easily by a measuring shunt which is wired into the load circuit.

Commercially available analog comparator circuits, which are inexpensive, may be used for the comparator circuit. The wiring of the comparator can be of a conventional nature, so it does not need to be described in more detail here.

### BRIEF DESCRIPTION OF THE DRAWINGS

To illustrate the invention further, reference will be made in the following portion of the description to the drawings, in which further advantageous embodiments, details and developments of the invention can be found. In the drawings:

FIG. 1 shows an exemplary embodiment of the invention schematically illustrated with the aid a block diagram,

FIG. 2 is a graph in which limiting of the power dissipation is shown schematically as a function of time,

FIG. 3 shows a graph in which a group of limit curves of maximum admissible values of the drain source voltage and the drain current of a MOS field effect transistor is illustrated; the parameter of this group of limit curves is the pulse time.

### DETAILED DESCRIPTION

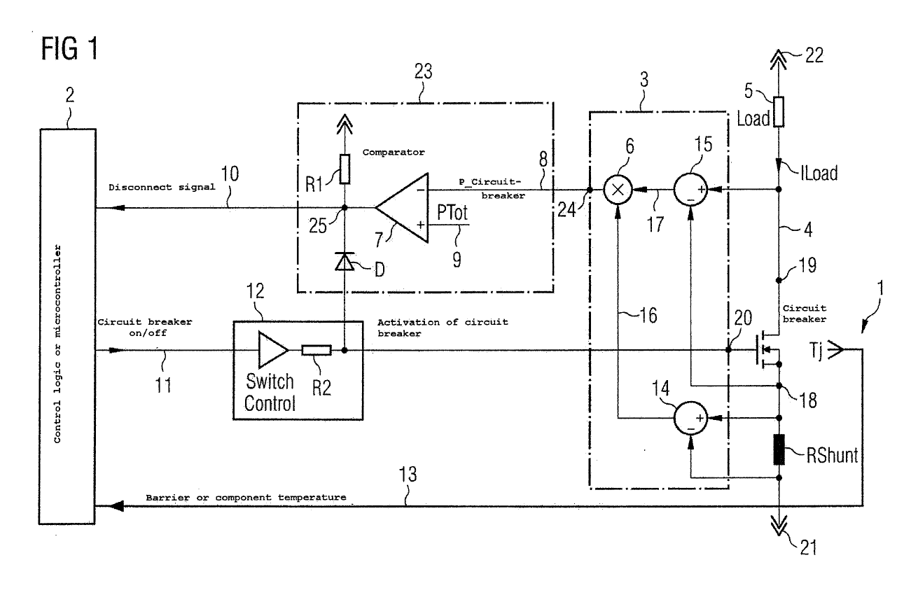

FIG. 1 shows an exemplary embodiment of the invention schematically illustrated with the aid a block diagram. A power semiconductor switch 1 is embodied as an N-channel MOS field effect transistor. The MOS field effect transistor 1 is connected by means of its power circuit terminals 19 and 18 into a load circuit 4. A load is designated by reference numeral 5 in the load circuit 4. Reference numerals 21, 22 indicate the connection of the load circuit 4 to terminals of a supply voltage.

The power semiconductor switch 1 comprises a control input 20, a gate terminal in the present case, which is connected via a control line 11 to a control unit 2. The power semiconductor switch 1 is switched off and on according to the application via the control line 11 by control signals, i.e. a control voltage which is conditioned in a driver circuit 12. Overtemperature monitoring 13 provided in this exemplary embodiment detects the heat loss that occurs during operation of the power semiconductor switch 1 and passes this information to the control unit 2. Overtemperature monitoring 13 corresponds to the “smart switch” described in the introduction and per se is not of central importance to the invention. Essential to the invention are, by contrast, the circuits 3 and 23 in FIG. 1.

Reference numeral 3 denotes a measuring circuit enclosed by broken lines and which provides an analog power dissipation signal 8 at an output 24. This power dissipation signal 8 is supplied to a comparator circuit 23 which is also enclosed by broken lines in FIG. 1.

The instantaneous values of the power dissipation signal 8 correspond to the instantaneous power dissipation that occurs during operation of the power semiconductor switch 1, i.e. the Joule heat loss in the power semiconductor switch 1. The measuring circuit 3 generates the power dissipation signal 8 in an analog multiplier 6 to which a first signal 17 and a second signal 16 are supplied. The first signal 17 is the drain source voltage of the MOS field effect transistor. It is detected by an analog voltage measuring circuit 15. The second signal 16 is proportional to the load current in the load circuit 4 and is detected by a current measuring circuit 14 at a measuring shunt Rshunt.

The comparator circuit 23 substantially comprises a comparator 7 to which the analog power dissipation signal 8 generated in the measuring circuit 3 is supplied at an inverting input. A reference voltage 9 is supplied to the non-inverting input of the comparator 7. The reference voltage 9 corresponds to a maximum pulse power dissipation specified by the manufacturer of the power semiconductor switch 1.

The comparator 7 compares the voltages present at the inputs. If the currently detected power dissipation voltage 8 exceeds the reference voltage 9, an output signal 10 is generated at the output 25 of the comparator circuit 23 and is returned via diode D and control line 11 to the control input 20 of switch 1. This means that in the present circuit example the potential at the control terminal 20 of the MOS field effect transistor 1 is pulled to a low value (differential voltage of diode D plus saturation voltage of the operational amplifier 7). Consequently the MOS field effect transistor 1 is brought into the blocking state. The load current in the load circuit 4 is then interrupted. The voltage drop at the measuring shunt Rshunt drops to zero. As a consequence the shut-off signal 10 drops away. If the overload state persists, this regulating procedure also continues and as a result brings about limiting of the power dissipation. The controller 2 can optionally switch off the power semiconductor switch 1 at a later instant, caused for example by the overtemperature signal (or the shut-off signal likewise supplied to it, FIG. 1), so the analog control 3, 23 is of course completely suspended.

The circuit device according to the invention makes it possible to limit the power dissipation in the power semiconductor switch 1 much more quickly than would be possible by means of the overtemperature monitoring 13. As a result of the analog circuit implementation, power dissipation monitoring is independent of the response speed of the control circuit 2. Shut-off times of less than one microsecond are possible with a comparatively small circuit engineering overhead. Owing to this comparatively very short response time a power dissipation limit value of the power semiconductor that is admissible during pulse control operation may be used as the reference value. The power dissipation admissible in pulse control operation is always greater than the maximum admissible continuous power dissipation (DC limiting curve in FIG. 3). This is particularly advantageous with an application in automotive engineering, since short-circuit currents of several hundred amperes have to be shut off as quickly as possible in such a case. The invention allows the power dissipation that occurs during operation of the power semiconductor switch to be limited to safe values even with a comparatively high ambient temperature. As a result of the invention it is possible to counteract a damage scenario in which a power semiconductor switch shuts off unnoticed in the event of an overload, but suffers damage in the process, with the result that it does not fail completely until a later time.

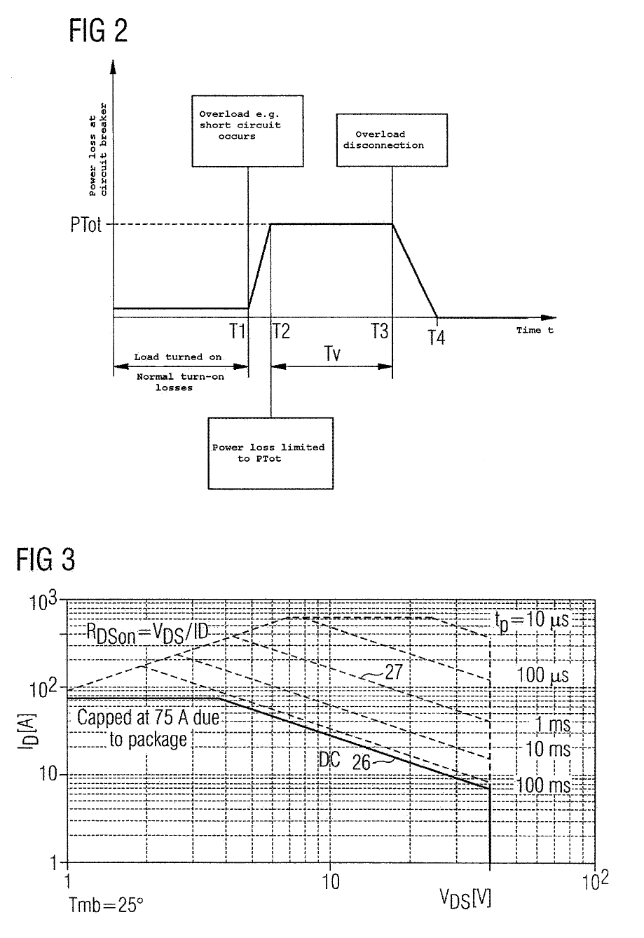

FIG. 2 schematically outlines the course over time of limiting of the power dissipation at the power switch. An overload, for example a short circuit, occurs at time T1. The inventive limiting of the power dissipation starts at time T2. The limit value is in this case the maximum admissible power dissipation value, specified by the manufacturer of the power semiconductor switch 1 for a specific temperature, in pulse control operation (FIG. 3). Following a delay Tv the overload is switched off at time T3 by the controller 2 which is closed at time T4.

FIG. 3 shows by way of example a graph of the admissible operating range of a MOS field effect transistor. The drain source voltage (V_{DS}) is plotted on the abscissa and the drain current (I_{D}) on the ordinate. Reference numeral 26 designates the maximum admissible power dissipation in continuous operation at an ambient temperature of 25° C. The characteristic curves shown by broken lines show admissible drain current and drain source voltage values during pulse-form operation. The parameter of these characteristic curves shown by broken lines is the pulse time tp (tp=10 microseconds to tp=100 milliseconds in FIG. 1). Reference numeral 27 singles out by way of example a power dissipation curve at a pulse time of 1 millisecond.

List of Reference Numerals Used

1 Power semiconductor switch
2 Control unit
3 Measuring circuit
4 Load circuit
5 Load
6 Multiplier circuit
7 On-off controller
8 Power dissipation signal
9 Reference signal
10 Shut-off signal
11 Control line
12 Power driver
13 Overtemperature monitoring
14 Current measuring circuit
15 Voltage measuring circuit
16 Second signal
17 First signal
18 Power circuit terminal
19 Power circuit terminal
20 Control input
21 Supply voltage terminal
22 Supply voltage terminal
23 Comparator circuit
24 Measuring circuit output
25 Comparator circuit output
26 Limiting curve, safe operating range at 25° C.
27 Limiting curve at a pulse time tp=1 millisecond

What is claimed is:

1. A method for limiting the power dissipation of a power semiconductor switch having a control input, comprising the following steps:
generating an analog power dissipation signal which is an image of the current power dissipation occurring during operation of the power semiconductor switch and which has a signal level,
comparing the signal level of the current power dissipation with a signal level of a reference signal,
generating a shut-off signal if the signal level of the power dissipation signal is greater than the signal level of the reference signal,
shutting off the power semiconductor switch via the shut-off signal.

2. A method according to claim 1, comprising the step of generating the power dissipation signal by multiplying a first signal which corresponds to the differential voltage at the power circuit terminals of the power semiconductor switch by a second signal which corresponds to the load current carried by the power circuit terminals.

3. A method according to claim 2, wherein the second signal is formed by a voltage drop which is caused by the load current at a measuring shunt.

4. A method according to claim 1, comprising the step of supplying the analog power dissipation signal to an inverting input of a comparator circuit and the reference signal to a non-inverting input of the comparator circuit.

5. A method according to claim 1, wherein a maximum admissible pulse power dissipation of the power semiconductor switch at a predetermined temperature is chosen as the reference signal.

6. A circuit arrangement for limiting the power dissipation of a power semiconductor switch which has a control input, comprising:
a measuring circuit which generates an analog power dissipation signal, the signal level of which corresponds to the power dissipation instantaneously occurring in the power semiconductor switch during operation,
a comparator circuit which has an output that is connected to the control input, which carries out a comparison of the signal level of the current power dissipation with a signal level of a reference signal, and which generates a shut-off signal if the signal level of the power dissipation signal is greater than the signal level of the reference signal.

7. A circuit arrangement according to claim 6, wherein the measuring circuit comprises an analog multiplier circuit which generates the power dissipation signal by multiplying a first signal which corresponds to the differential voltage at the power circuit terminals of the power semiconductor switch by a second signal which corresponds to the current carried via the power circuit terminals of the power semiconductor switch.

8. A circuit arrangement according to claim 7, wherein the load current of the power semiconductor switch is carried via a measuring shunt and the second signal corresponds to the voltage drop occurring at this measuring shunt during operation of the power semiconductor switch.

9. A circuit arrangement according to claim 6, wherein the reference signal is a maximum admissible pulse power dissipation of the power semiconductor switch at a predetermined temperature.

10. A circuit arrangement according to claim 6, further comprising a microcontroller coupled between the comparator and the power semiconductor switch.

11. A circuit arrangement according to claim 10, wherein the power semiconductor switch comprises a temperature sensor coupled with said microcontroller.

12. A circuit arrangement for limiting the power dissipation of a power semiconductor switch which has a control input, comprising:
a power measuring circuit coupled with the power semiconductor switch generating an output signal which is proportional to a dissipation power of the power semiconductor switch,
a comparator receiving the output signal and a reference input signal and comprising a control output coupled with the control input of the power semiconductor switch, the comparator being operable to generate a shut-off signal if the output signal is greater than the reference input signal.

13. A circuit arrangement according to claim 12, wherein the measuring circuit comprises an analog multiplier circuit which generates the output signal by multiplying a first signal which corresponds to the differential voltage at the power circuit terminals of the power semiconductor switch by a second signal which corresponds to the current carried via the power circuit terminals of the power semiconductor switch.

14. A circuit arrangement according to claim 13, wherein the load current of the power semiconductor switch is carried via a measuring shunt and the second signal corresponds to the voltage drop occurring at this measuring shunt during operation of the power semiconductor switch.

15. A circuit arrangement according to claim 12, wherein the reference signal is a maximum admissible pulse power dissipation of the power semiconductor switch at a predetermined temperature.

16. A circuit arrangement according to claim 12, further comprising a microcontroller coupled between the comparator and the power semiconductor switch.

17. A circuit arrangement according to claim 16, wherein the power semiconductor switch comprises a temperature sensor coupled with said microcontroller.
